(19) United States
(12) Patent Application Publication
(10) Pub. No.: US 2024/0055394 A1
(43) Pub. Date: Feb. 15, 2024

(54) SEMICONDUCTOR PACKAGE

(71) Applicant: SAMSUNG ELECTRONICS CO., LTD., SUWON-Si (KR)

(72) Inventor: DAEHO LEE, SUWON-SI (KR)

(21) Appl. No.: 18/320,138

(22) Filed: May 18, 2023

(30) Foreign Application Priority Data
Aug. 12, 2022 (KR) 10-2022-0101254

(51) Int. Cl. H01L 25/03; H01L 23/00; H01L 23/31; H01L 23/538; H01L 25/00; H01L 21/56

(52) U.S. Cl. CPC H01L 25/03; H01L 24/16; H01L 23/3128; H01L 23/3135; H01L 23/5383; H01L 23/5385; H01L 23/5386; H01L 25/50; H01L 21/561; H01L 2224/16227

(57) ABSTRACT

A semiconductor package includes a package substrate, a first chip structure mounted on the package substrate, a first semiconductor chip mounted on the first chip structure, and a first molding layer that surrounds the first chip structure and the first semiconductor chip on the package substrate. The first chip structure includes a second semiconductor chip, a second molding layer on a lateral surface of the second semiconductor chip, a first redistribution layer on the second semiconductor chip and the second molding layer, and a first through electrode on a side of the second semiconductor chip and connected to the first redistribution layer.

### CROSS-REFERENCE TO RELATED APPLICATION

This U.S. nonprovisional patent application claims priority under 35 U.S.C § 119 to Korean Patent Application No. 10-2022-0101254, filed on Aug. 12, 2022, in the Korean Intellectual Property Office, the disclosure of which is incorporated by reference in its entirety herein.

### TECHNICAL FIELD

The present inventive concepts relate to a semiconductor package, and more particularly, to a stacked semiconductor package and a method of fabricating the same.

### DISCUSSION OF RELATED ART

Portable devices have been increasingly demanded in recent electronic product markets. As a result, electronic parts mounted on the portable devices need to have a reduced size and weight. Memory devices among the electronic parts need to achieve a high bandwidth or provide a high processing capacity.

There is need for technology to integrate a number of individual devices into a single package as well as technology to reduce individual sizes of mounting parts to accomplish the reduction in size and weight of the electronic parts. In particular, semiconductor packages operated at high frequency signals are required to have compactness and excellent electrical characteristics.

A through-silicon via (TSV) is a type of vertical interconnect access (via) connection that allows for stacking of semiconductor devices. However, a TSV process for stacking semiconductor devices is complex and excessively expensive.

### SUMMARY

Some embodiments of the present inventive concepts provide a semiconductor package with increased electrical properties and a method of fabricating the same.

Some embodiments of the present inventive concepts provide a semiconductor package with increased structural stability and a method of fabricating the same.

Some embodiments of the present inventive concepts provide a simplified and low-cost method of fabricating a semiconductor package and a semiconductor package fabricated by the same.

According to an example embodiment of the present inventive concept, a semiconductor package includes: a package substrate; a first chip structure mounted on the package substrate; a first semiconductor chip mounted on the first chip structure; and a first molding layer that surrounds the first chip structure and the first semiconductor chip on the package substrate. The first chip structure includes: a second semiconductor chip; a second molding layer disposed on a lateral surface of the second semiconductor chip; a first redistribution layer disposed on the second semiconductor chip and the second molding layer; and a first through electrode disposed on a side of the second semiconductor chip and connected to the first redistribution layer.

According to an example embodiment of the present inventive concept, a semiconductor package includes: a package substrate; a first semiconductor chip flip-chip mounted on the package substrate; a first molding layer that surrounds a lateral surface of the first semiconductor chip; a first through electrode that vertically penetrates the first molding layer and is mounted on the package substrate through a first connection terminal on a bottom surface of the first molding layer; a first redistribution layer disposed on the first semiconductor chip and the first molding layer, the first redistribution layer being coupled to the first through electrode; a second semiconductor chip flip-chip mounted on the first redistribution layer; and a second molding layer disposed on the package substrate, the second molding layer covering the first molding layer, the first redistribution layer, and the second semiconductor chip.

According to an example embodiment of the present inventive concept, a semiconductor package includes: a package substrate; a first chip structure disposed on the package substrate; and a first semiconductor chip disposed on the first chip structure. The first chip structure includes: a second semiconductor chip; a vertical connection terminal disposed on a side of the second semiconductor chip; and a first redistribution layer disposed on the second semiconductor chip and the vertical connection terminal, the first redistribution layer being electrically connected to the vertical connection terminal, and on which is mounted the first semiconductor chip. The second semiconductor chip is mounted on the package substrate through a first connection terminal between the package substrate and the second semiconductor chip. The vertical connection terminal is mounted on the package substrate through a second connection terminal between the package substrate and the vertical connection terminal.

According to an embodiment of the present inventive concept, a method of fabricating a semiconductor package includes: forming first semiconductor chips; forming a first molding layer that surrounds the first semiconductor chips; forming through electrodes that vertically penetrate the first molding layer; forming a redistribution layer on the first semiconductor chips and the first molding layer; performing a cutting process to divide the first semiconductor chips to form a chip structure; using a flip chip manner to mount the chip structure on a package substrate; flip chip mounting a second semiconductor chip on the redistribution layer of the chip structure; and forming on the package substrate a second molding layer that covers the chip structure and the second semiconductor chip.

### BRIEF DESCRIPTION OF THE DRAWINGS

FIG. 1 illustrates a cross-sectional view showing a semiconductor device according to an example embodiment of the present inventive concept.

FIG. 2 illustrates a plan view showing a semiconductor device according to an example embodiment of the present inventive concept.

FIGS. 3 and 4 illustrate cross-sectional views showing a semiconductor device according to an example embodiment of the present inventive concept.

FIG. 5 illustrates a plan view showing a semiconductor device according to an example embodiment of the present inventive concept.

FIG. 6 illustrates a cross-sectional view showing a semiconductor device according to an example embodiment of the present inventive concept.

FIG. 7 illustrates a plan view showing a semiconductor device according to an example embodiment of the present inventive concept.

FIGS. 8, 9, 10, 11 and 12 illustrate cross-sectional views showing a semiconductor package according to an example embodiment of the present inventive concept.

FIGS. 13, 14, 15, 16, 17, 18, 19, 20, 21, 22, 23, 24 and 25 illustrate cross-sectional views showing a method of fabricating a semiconductor device according to an example embodiment of the present inventive concept.

### DETAILED DESCRIPTION OF EMBODIMENTS

The following will now describe a semiconductor package according to the present inventive concepts with reference to the accompanying drawings.

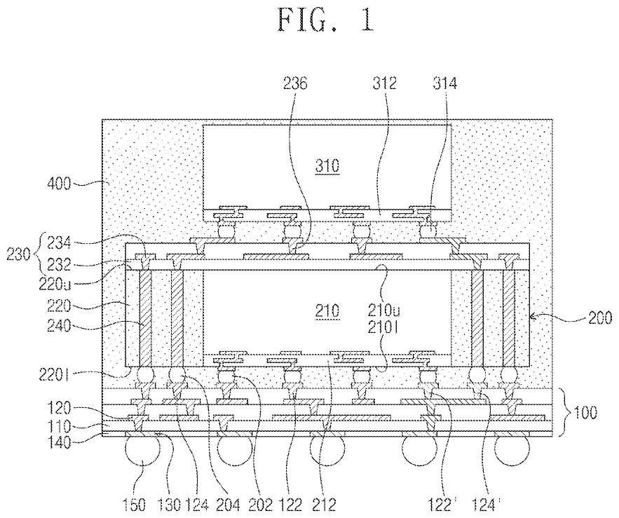

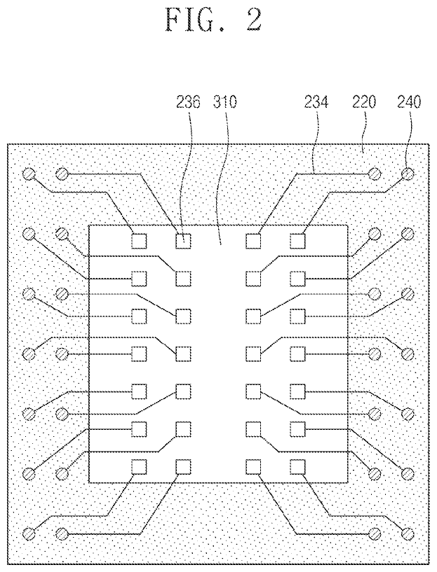

FIG. 1 illustrates a cross-sectional view showing a semiconductor device according to an example embodiment of the present inventive concept. FIG. 2 illustrates a plan view showing a semiconductor device according to an example embodiment of the present inventive concept.

Referring to FIGS. 1 and 2, a package substrate 100 is provided. The package substrate 100 may be a redistribution substrate. For example, the package substrate 100 may include one or more first substrate wiring layers that are stacked on each other. Each of the first substrate wiring layers may include a first substrate dielectric pattern 110 and one or more first substrate wiring patterns 120 in the first substrate dielectric pattern 110. The first substrate wiring pattern 120 in one first substrate wiring layer may be electrically connected to the first substrate wiring pattern 120 in an adjacent another first substrate wiring layer.

The first substrate dielectric pattern 110 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. Alternatively, the first substrate dielectric pattern 110 may include a dielectric material. For example, the first substrate dielectric pattern 110 may include silicon oxide (SiO), silicon nitride (SiN), silicon oxynitride (SiON), or dielectric polymers.

The first substrate wiring pattern 120 may be provided on the first substrate dielectric pattern 110. The first substrate wiring pattern 120 may horizontally extend on the first substrate dielectric pattern 110. The first substrate wiring pattern 120 may be provided on a top surface of the first substrate dielectric pattern 110. The first substrate wiring pattern 120 may protrude onto the top surface of the first substrate dielectric pattern 110. On the first substrate dielectric pattern 110, the first substrate wiring pattern 120 may be covered with another first substrate dielectric pattern 110 disposed on the first substrate dielectric pattern 110. The first substrate wiring pattern 120 provided on an uppermost first substrate wiring layer may serve as a substrate pad to which is coupled a first chip structure 200 which will be discussed below. For example, some of the first substrate wiring patterns 120 provided on the uppermost first substrate wiring layer may be first substrate pads 122 on which is mounted a first semiconductor chip 210 of a first chip structure 200, and others of the first substrate wiring patterns 120 provided on the uppermost first substrate wiring layer may be second substrate pads 124 to which are coupled first through electrodes 240 of the first chip structure 200. The first substrate wiring pattern 120 may be a pad part or a line part of the first substrate wiring layer. For example, the first substrate wiring pattern 120 may be a component for horizontal redistribution in the package substrate 100. The first substrate wiring pattern 120 may include a conductive material. For example, the first substrate wiring pattern 120 may include metal, such as copper (Cu).

The first substrate wiring pattern 120 may have a damascene structure. For example, the first substrate wiring pattern 120 may have a via that protrudes onto a bottom surface thereof. The via may be a component for vertical connection between the first substrate wiring patterns 120 of neighboring first substrate wiring layers. Alternatively, the via may be a component for connection between an external pad 130 and the first substrate wiring pattern 120 of a lowermost first substrate wiring layer. For example, the vias may penetrate from the bottom surface of the first substrate wiring pattern 120 through the first substrate dielectric pattern 110 to be coupled to a top surface of the first substrate wiring pattern 120 of an underlying another first substrate wiring layer. In another example, the via may penetrate from the bottom surface of the first substrate wiring pattern 120 through a lowermost first substrate dielectric pattern 110 to be coupled to a top surface of the external pad 130. In this configuration, an upper portion of the first substrate wiring pattern 120 may be a head part used as a horizontal line or pad, and the via of the first substrate wiring pattern 120 may be a tail part. The first substrate wiring pattern 120 may have a T shape.

One or more external pads 130 may be provided on a bottom surface of the lowermost first substrate wiring layer. The external pads 130 may be electrically connected to the first substrate wiring patterns 120. The external pads 130 may serve as pads to which external terminals 150 are coupled.

A substrate protection layer 140 may be provided. The substrate protection layer 140 may cover the bottom surface of the lowermost first substrate wiring layer and expose the external pads 130. The external pads 130 may be provided with external terminals 150 on exposed bottom surfaces thereof. The external terminals 150 may include solder balls or solder bumps, and based on type of the external terminals 150, a semiconductor package may be provided in the form of one of a ball grid array (BGA) type, a fine ball-grid array (FBGA) type, and a land grid array (LGA) type.

The package substrate 100 may be configured as discussed above. The present inventive concepts, however, are not limited thereto. The package substrate 100 may be a printed circuit board (PCB). For example, the package substrate 100 may have a core layer and peripheral parts for wiring connections on top and bottom sides of the core layer.

A first chip structure 200 may be disposed on the package substrate 100. The first chip structure 200 may include a first semiconductor chip 210, a first molding layer 220, a first redistribution layer 230, and first through electrodes 240. The following will describe in detail a configuration of the first chip structure 200.

The first semiconductor chip 210 may include a semiconductor material, such as silicon (Si). The first semiconductor chip 210 may include a first circuit layer 212. The first circuit layer 212 may include a memory circuit. For example, the first semiconductor chip 210 may be a memory chip. The present inventive concepts, however, are not limited thereto, and the first semiconductor chip 210 may include a logic chip or a passive element. A bottom surface 210l of the first semiconductor chip 210 may be an active surface, and a top surface 210u of the first semiconductor chip 210 may be an inactive surface. For example, the first semiconductor chip 210 may be disposed in a face-down state on the package substrate 100. For example, the active surface may contact an active region of the first semiconductor chip 210 that may include at least one transistor.

The first molding layer 220 may be provided on a side of the first semiconductor chip 210. When viewed in a plan view, the first molding layer 220 may surround the first semiconductor chip 210. The first molding layer 220 may cover lateral or outer surfaces of the first semiconductor chip 210. In this case, the first molding layer 220 may be in contact with the lateral surfaces of the first semiconductor chip 210. The first molding layer 220 may have a top surface 220u located at the same level as that of the top surface 210u of the first semiconductor chip 210. For example, the top surface 220u of the first molding layer 220 may be coplanar with the top surface 210u of the first semiconductor chip 210. The first molding layer 220 may have a bottom surface 2201 located at the same level as that of the bottom surface 210l of the first semiconductor chip 210. For example, the bottom surface 2201 of the first molding layer 220 may be coplanar with the bottom surface 210l of the first semiconductor chip 210. When viewed in a direction parallel to the lateral surfaces of the first semiconductor chip 210, the first molding layer 220 may have the same width as that of the first semiconductor chip 210. The first molding layer 220 may include a dielectric material, such as an epoxy molding compound (EMC).

At least one first through electrode 240 may be disposed on a side of the first semiconductor chip 210. The first through electrodes 240 may be disposed horizontally spaced apart from the first semiconductor chip 210. The first through electrode 240 may vertically penetrate the first molding layer 220. An end of the first through electrodes 240 may extend toward the package substrate 100 to be exposed on the bottom surface 2201 of the first molding layer 220. A bottom surface of the first through electrodes 240 may be coplanar with the bottom surface 2201 of the first molding layer 220. In this case, the bottom surface 2201 of the first molding layer 220 may be flat, and the bottom surface of the first through electrode 240 may also be flat. Another end of the first through electrode 240 may extend toward the first redistribution layer 230 to be exposed on the top surface 220u of the first molding layer 220. A top surface of the first through electrode 240 may be coplanar with the top surface 220u of the first molding layer 220. In this case, the top surface 220u of the first molding layer 220 may be flat, and the top surface of the first through electrode 240 may also be flat. The first through electrodes 240 may have a circular or polygonal pillar shape that vertically penetrates the first molding layer 220. The first through electrode 240 may have a width that is uniform irrespective of distance from the package substrate 100. Alternatively, the first through electrode 240 may have a width that decreases with decreasing distance from the package substrate 100. The first through electrode 240 may be provided in plural, if necessary. For example, when viewed in a plan view as shown in FIG. 2, the first through electrodes 240 may be disposed on opposite sides of the first semiconductor chip 210 or arranged to surround the first semiconductor chip 210. In this case, the second substrate pad 124 may also be provided in plural coupled to the first through electrodes 240. The first through electrodes 240 may include metal. For example, the first through electrodes 240 may include copper (Cu).

The first redistribution layer 230 may be disposed on the first semiconductor chip 210 and the first molding layer 220. The first redistribution layer 230 may be in direct contact with the top surface 210u of the first semiconductor chip 210 and the top surface 220u of the first molding layer 220.

The first redistribution layer 230 may include one or more second substrate wiring layers that are stacked on each other. Each of the second substrate wiring layers may include a second substrate dielectric pattern 232 and one or more second substrate wiring patterns 234 in the second substrate dielectric pattern 232. When the second substrate wiring layer is provided in plural, the second substrate wiring pattern 234 in one second substrate wiring layer may be electrically connected to the second substrate wiring pattern 234 in an adjacent another second substrate wiring layer.

The second substrate dielectric pattern 232 may include a dielectric polymer or a photo-imageable dielectric (PID). For example, the photo-imageable dielectric may include at least one selected from photosensitive polyimide (PI), polybenzoxazole (PBO), phenolic polymers, and benzocyclobutene polymers. Alternatively, the second substrate dielectric pattern 232 may include a dielectric material. For example, the second substrate dielectric pattern 232 may include silicon oxide (SiO), silicon nitride (SiN), silicon oxynitride (SiON), or dielectric polymers.

The second substrate wiring pattern 234 may be disposed on the second substrate dielectric pattern 232. The second substrate wiring pattern 234 may horizontally extend on the second substrate dielectric pattern 232. The second substrate wiring pattern 234 may be provided on a top surface of the second substrate dielectric pattern 232. The second substrate wiring pattern 234 may protrude onto the top surface of the second substrate dielectric pattern 232. On the second substrate dielectric pattern 232, the second substrate wiring pattern 234 may be covered with another second substrate dielectric pattern 232 disposed on the second substrate dielectric pattern 232. The second substrate wiring patterns 234 on an uppermost second substrate wiring layer may be redistribution pads 236 to which a second semiconductor chip 310 is coupled as discussed below. The second substrate wiring pattern 234 may be a pad part or a line part of the second substrate wiring layer. In this sense, the second substrate wiring pattern 234 may be a component for horizontal redistribution in the second substrate wiring layer. For example, as shown in FIG. 2, the second substrate wiring patterns 234 may connect the redistribution pads 236 to the first through electrodes 240. The first through electrodes 240 may correspond to vertical connection terminals through which an electrical connection of the first redistribution layer 230 extends toward the package substrate 100. FIG. 2 depicts by way of example an electrical connection of the second substrate wiring pattern 234, and a shape and arrangement of the second substrate wiring pattern 234 is not limited to that illustrated in FIG. 2. The second substrate wiring pattern 234 may include a conductive material. For example, the second substrate wiring pattern 234 may include copper (Cu).

The second substrate wiring pattern 234 may have a damascene structure. For example, the second substrate wiring pattern 234 may have a head part and a tail part that are connected into a single unitary piece. The head and tail parts of the second substrate wiring pattern 234 may have a T shape when viewed in a vertical section view.

The head part of the second substrate wiring pattern 234 may be a line part or a pad part that horizontally expands a wiring line in the first redistribution layer 230. The head part may be provided on the top surface of the second substrate dielectric pattern 232. For example, the head part may protrude onto the top surface of the second substrate dielectric pattern 232.

The tail part of the second substrate wiring pattern 234 may be a via part for vertical connection of a wiring line in the first redistribution layer 230. The tail part may be coupled to another second substrate wiring layer disposed thereunder. For example, the tail part of the second substrate wiring pattern 234 may extend from a bottom surface of the head part, and may penetrate the second substrate dielectric pattern 232 to be coupled to the head part of the second substrate wiring pattern 234 of an underlying another second substrate wiring layer. The tail part of the second substrate wiring pattern 234 of a lowermost one of the second substrate wiring layers may penetrate the second substrate dielectric pattern 232 to be exposed on a bottom surface of the first redistribution layer 230. In this case, the tail part of the second substrate wiring pattern 234 of the lowermost second substrate wiring layer may be positioned on the first molding layer 220. The tail part of the second substrate wiring pattern 234 of the lowermost second substrate wiring layer may be coupled to the first through electrode 240.

The first chip structure 200 may be provided with connection terminals 202 and 204 on a bottom surface thereof. The connection terminals 202 and 204 may include first connection terminals 202 provided on the bottom surface 210l of the first semiconductor chip 210 and second connection terminals 204 provided on the bottom surfaces of the first through electrodes 240. The first connection terminals 202 may be electrically connected to an input/output circuit (or a memory circuit), a power circuit, or a ground circuit of the first semiconductor chip 210. The connection terminals 202 and 204 may include, for example, solder balls.

The first chip structure 200 may be mounted on the package substrate 100. For example, the first chip structure 200 may be electrically connected through the connection terminals 202 and 204 to the package substrate 100. The first connection terminals 202 may be provided between the first substrate pads 122 of the package substrate 100 and the first circuit layer 212 of the first semiconductor chip 210. The second connection terminals 204 may be provided between the first through electrodes 240 and the second substrate pads 124 of the package substrate 100. Since the first chip structure 200 is mounted through the connection terminals 202 and 204 on the package substrate 100, the bottom surface of the first chip structure 200 may be spaced apart from the package substrate 100. For example, the bottom surface 210l of the first semiconductor chip 210 and the bottom surfaces of the first through electrodes 240 may be spaced apart from a top surface of the package substrate 100.

An under-fill layer may be provided between the package substrate 100 and the first chip structure 200. The under-fill layer may surround the connection terminals 202 and 204 while filling a space between the package substrate 100 and the first semiconductor chip 210 and a space between the package substrate 100 and the first molding layer 220.

A second semiconductor chip 310 may be disposed on the first chip structure 200. The second semiconductor chip 310 may be positioned above the first semiconductor chip 210. For example, the second semiconductor chip 310 may vertically overlap the first semiconductor chip 210. In other words, the second semiconductor chip 310 may be positioned on a central portion of the first chip structure 200. The second semiconductor chip 310 may include a semiconductor material, such as silicon (Si). The second semiconductor chip 310 may include a second circuit layer 312. The second semiconductor chip 310 may be of the same type as the first semiconductor chip 210. For example, the second circuit layer 312 may include a memory circuit. In this sense, the second semiconductor chip 310 may be a memory chip. The present inventive concepts, however, are not limited thereto, and the second semiconductor chip 310 may include a logic chip or a passive element. It is not required that the second semiconductor chip 310 be of the same type as the first semiconductor chip 210. According to an example embodiment, the second semiconductor chip 310 and the first semiconductor chip 210 are semiconductor chips of different types. A bottom surface of the second semiconductor chip 310 may be an active surface, and a top surface of the second semiconductor chip 310 may be an inactive surface. For example, the second semiconductor chip 310 may be disposed in a face-down state on the first chip structure 200. For example, the active surface may contact an active region of the second semiconductor chip 310 that includes at least one transistor.

The second semiconductor chip 310 may be provided with third connection terminals 314 on the bottom surface thereof. The third connection terminals 314 may be electrically connected to an input/output circuit (or a memory circuit), a power circuit, or a ground circuit of the second semiconductor chip 310. The third connection terminals 314 may include, for example, solder balls.

The second semiconductor chip 310 may be mounted on the first chip structure 200. For example, the second semiconductor chip 310 may be electrically connected through the third connection terminals 314 to the first redistribution layer 230 of the first chip structure 200. The third connection terminals 314 may be disposed between the redistribution pads 236 of the first redistribution layer 230 in the first chip structure 200 and the second circuit layer 312 of the second semiconductor chip 310. The second semiconductor chip 310 may be electrically connected to the package substrate 100 through the first redistribution layer 230 and the first through electrodes 240 of the first chip structure 200. Since the second semiconductor chip 310 is mounted through the third connection terminals 314 on the first chip structure 200, the bottom surface of the second semiconductor chip 310 may be spaced apart from the first chip structure 200.

An under-fill layer may be disposed between the first chip structure 200 and the second semiconductor chip 310. The under-fill layer may surround the third connection terminals 314 while filling a space between the first chip structure 200 and the second semiconductor chip 310.

According to an example embodiment of the present inventive concept, the first semiconductor chip 210 and the second semiconductor chip 310 are vertically stacked without through vias that penetrate the first semiconductor chip 210 and the second semiconductor chip 310. In addition, the first semiconductor chip 210 and the second semiconductor chip 310 may each be mounted in a flip-chip bonding manner whose electrical connection length is less than that of a wire bonding manner. For example, each of the first semiconductor chip 210 and the second semiconductor chip 310 may be flip-chip mounted. Accordingly, it may be possible to provide a semiconductor package with a lower manufacturing cost and higher electrical properties.

Referring still to FIGS. 1 and 2, the first semiconductor chip 210 and the second semiconductor chip 310 may be coupled to the same wiring circuit. For example, the first substrate pads 122 may have ones 122′ to which the first semiconductor chip 210 is coupled, and the second substrate pads 124 may have ones 124′ to which the first through electrodes 240 are coupled, which first and second substrate pads 122′ and 124′ are electrically connected to each other in the package substrate 100. When the first semiconductor chip 210 and the second semiconductor chip 310 are the same type of memory chip, at least a portion of a memory circuit of the first semiconductor chip 210 and at least a portion of a memory circuit of the second semiconductor chip 310 may be connected to each other through the ones 122′ of the first substrate pads 122, the ones 124′ of the second substrate pads 124, and the first through electrodes 240. Alternatively, even when the first semiconductor chip 210 and the second semiconductor chip 310 are different semiconductor chips from each other, at least a portion of a power/ground circuit of the first semiconductor chip 210 and at least a portion of a power/ground circuit of the second semiconductor chip 310 may be connected to each other through the ones 122′ of the first substrate pads 122, the ones 124′ of the second substrate pads 124, and the first through electrodes 240.

According to an example embodiment of the present inventive concept, the first semiconductor chip 210 and the second semiconductor chip 310 partially share a circuit of the package substrate 100, and thus there may be a reduction in area required for wiring of the package substrate 100. As a result, it may be possible to provide a compact-sized semiconductor package. In addition, it may be possible to provide a semiconductor package with fewer wiring lines in the package substrate 100 and with greater electrical properties.

Referring again to FIGS. 1 and 2, a second molding layer 400 may be disposed on the package substrate 100. The second molding layer 400 may cover the top surface of the package substrate 100. The second molding layer 400 may surround the first chip structure 200 and the second semiconductor chip 310. FIG. 1 depicts that the second molding layer 400 covers the top surface of the second semiconductor chip 310, but the present inventive concepts are not limited thereto. The second molding layer 400 may expose the top surface of the second semiconductor chip 310. In this case, if necessary, a thermal radiation member may be disposed on the top surface of the second semiconductor chip 310. The second molding layer 400 may include a dielectric material. For example, the second molding layer 400 may include an epoxy molding compound (EMC).

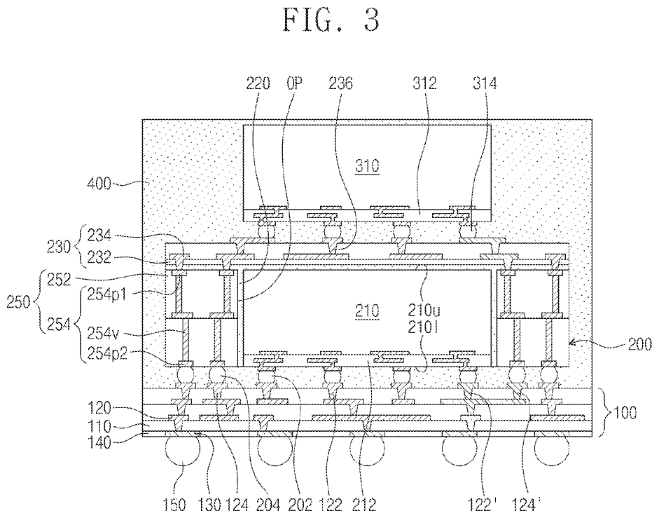

FIG. 3 illustrates a cross-sectional view showing a semiconductor device according to an example embodiment of the present inventive concept. In the embodiment that follows, components the same as those discussed in the embodiment of FIGS. 1 and 2 are allocated with the same reference numerals, and a repetitive explanation thereof will be omitted or abridged for convenience of description. The following will focus on differences between the embodiment of FIGS. 1 and 2 and the other embodiment described below.

Referring to FIG. 3, the first chip structure 200 may further include a connection substrate 250. The connection substrate 250 may be disposed on the package substrate 100. The connection substrate 250 may have an opening OP that penetrates therethrough. For example, the opening OP may have an open hole that connects top and bottom surfaces of the connection substrate 250. The opening OP may be positioned on a central region of the package substrate 100. The top surface of the connection substrate 250 may be in contact with the bottom surface of the first redistribution layer 230. The connection substrate 250 may correspond to a vertical connection terminal connected to the first redistribution layer 230 on a side of the first semiconductor chip 210.

The connection substrate 250 may include a base layer 252 and a conductive member 254 that is a line pattern disposed in the base layer 252. For example, the base layer 252 may include silicon oxide (SiO). The conductive member 254 may occupy an outer side of the connection substrate 250, and the opening OP may occupy an inner side of the connection substrate 250.

The conductive member 254 may include upper pads 254p1, vias 254v, and lower pads 254p2. The upper pads 254p1 may be disposed in an upper portion of the connection substrate 250. The upper pads 254p1 may be exposed on the top surface of the connection substrate 250. The upper pads 254p1 may be electrically connected to the second substrate wiring patterns 234 of the first redistribution layer 230. For example, the second substrate wiring patterns 234 may penetrate the second substrate dielectric pattern 232 to be coupled to the upper pads 254p1. The connection substrate 250 may corresponding to vertical connection terminals through which an electrical connection of the first redistribution layer 230 extends toward the package substrate 100. The lower pads 254p2 may be disposed on the bottom surface of the connection substrate 250. The vias 254v may be through electrodes that penetrate the base layer 252 to electrically connect the upper pads 254p1 to the lower pads 254p2.

The first semiconductor chip 210 may be disposed in the opening OP of the connection substrate 250. When viewed in a plan view, the first semiconductor chip 210 may have a planar shape smaller than that of the opening OP. For example, the first semiconductor chip 210 may be spaced apart from an inner sidewall of the opening OP.

The first molding layer 220 may fill a space between the connection substrate 250 and the first semiconductor chip 210. For example, the first molding layer 220 may fill an unoccupied portion of the opening OP. The first molding layer 220 may cover the top surface of the connection substrate 250 and the top surface 210u of the first semiconductor chip 210. In this case, the second substrate wiring patterns 234 of the first redistribution layer 230 may penetrate the second substrate dielectric pattern 232 and the first molding layer 220, thereby being coupled to the upper pads 254p1. The bottom surface of the connection substrate 250, the bottom surface of the first molding layer 220, and the bottom surface 210l of the first semiconductor chip 210 may be coplanar with each other.

The first chip structure 200 may be mounted on the package substrate 100. For example, the first chip structure 200 may be electrically connected through the connection terminals 202 and 204 to the package substrate 100. The first connection terminals 202 may be disposed between the first substrate pads 122 of the package substrate 100 and the first circuit layer 212 of the first semiconductor chip 210. The second connection terminals 204 may be disposed between the second substrate pads 124 of the package substrate 100 and the lower pads 254p2 of the connection substrate 250.

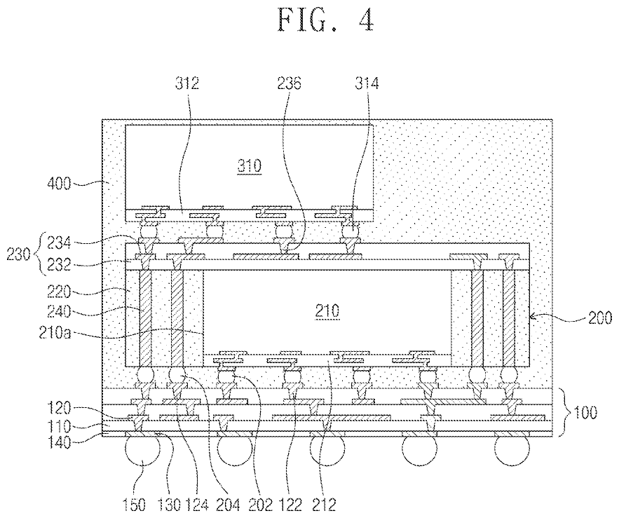

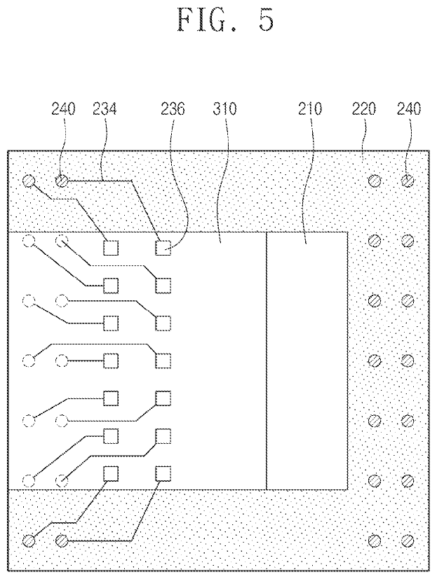

FIG. 4 illustrates a cross-sectional view showing a semiconductor device according to an example embodiment of the present inventive concept. FIG. 5 illustrates a plan view showing a semiconductor device according to an example embodiment of the present inventive concept. For convenience of description, FIG. 5 omits an illustration of some chip pads of a second semiconductor chip and some wiring lines of a first redistribution layer.

FIG. 1 depicts that the second semiconductor chip 310 vertically overlaps the first semiconductor chip 210, but the present inventive concepts are not limited thereto.

Referring to FIGS. 4 and 5, the second semiconductor chip 310 may be disposed adjacent to one of lateral surfaces of the first chip structure 200. For example, a portion of the second semiconductor chip 310 may be positioned on the first molding layer 220 adjacent to a first lateral surface 210a of the first semiconductor chip 210, and another portion of the second semiconductor chip 310 may be positioned on the first semiconductor chip 210. Thus, the second semiconductor chip 310 may vertically overlap a portion of the first molding layer 220 and a portion of the first semiconductor chip 210. The first lateral surface 210a of the first semiconductor chip 210 may be positioned below the second semiconductor chip 310. For example, when viewed in a plan view, the second semiconductor chip 310 may protrude from the first lateral surface 210a of the first semiconductor chip 210 in a direction from the first semiconductor chip 210 toward the first molding layer 220. The second semiconductor chip 310 may be horizontally shifted from the first semiconductor chip 210.

According to an example embodiment of the present inventive concept, the second semiconductor chip 310 may be connected to the package substrate 100 through the first redistribution layer 230 and the first through electrodes 240 in the first molding layer 220. As shown in FIG. 5, the second semiconductor chip 310 may be disposed to rest on the first molding layer 220, and the first redistribution layer 230 may have one or more wiring lines having their reduced lengths for connection between the second semiconductor chip 310 and the first through electrodes 240. As a result, there may be provided a semiconductor package whose electrical properties are increased.

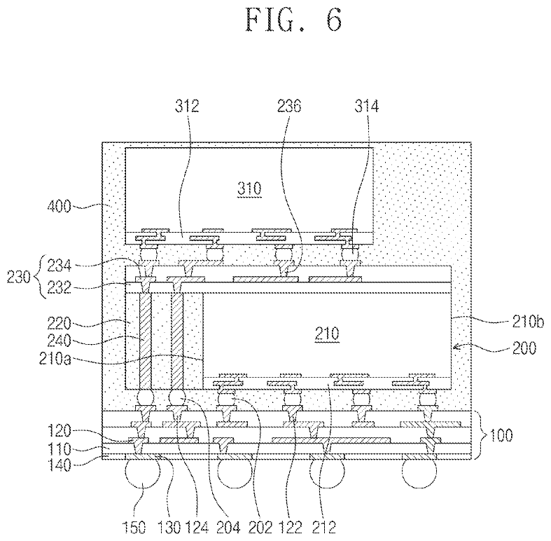

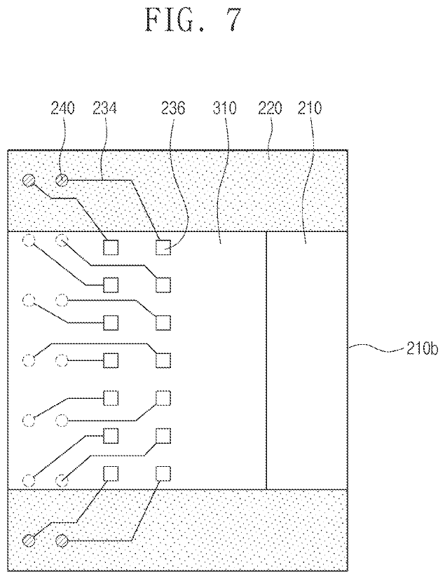

FIG. 6 illustrates a cross-sectional view showing a semiconductor device according to an example embodiment of the present inventive concept. FIG. 7 illustrates a plan view showing a semiconductor device according to an example embodiment of the present inventive concept. For convenience of description, FIG. 7 omits an illustration of some chip pads of a second semiconductor chip and some wiring lines of a first redistribution layer.

FIGS. 4 and 5 depict that the first molding layer 220 surrounds the first semiconductor chip 210, but the present inventive concepts are not limited thereto.

Referring to FIGS. 6 and 7, the second semiconductor chip 310 may be disposed adjacent to one of lateral surfaces of the first chip structure 200. The second semiconductor chip 310 may vertically overlap a portion of the first molding layer 220 and a portion of the first semiconductor chip 210. The second semiconductor chip 310 may be horizontally shifted from the first semiconductor chip 210.

The second semiconductor chip 310 may be electrically connected to the package substrate 100 through the first through electrodes 240 disposed adjacent to one lateral surface of the first chip structure 200, and thus neither the first molding layer 220 nor the first through electrodes 240 are disposed on a second lateral surface 210b of the first semiconductor chip 210 opposite to the first lateral surface 210a of the first semiconductor chip 210. For example, the first molding layer 220 may be only disposed on the first lateral surface 210a of the first semiconductor chip 210 and on lateral surfaces of the first semiconductor chip 210 between the first lateral surface 210a and the second lateral surface 210b. The second lateral surface 210b of the first semiconductor chip 210 may be exposed without being covered with the first molding layer 220. The first through electrodes 240 may be disposed adjacent to the first lateral surface 210a of the first semiconductor chip 210. Alternatively, the first through electrodes 240 may be disposed adjacent to the first lateral surface 210a of the first semiconductor chip 210 and to lateral surfaces of the first semiconductor chip 210 between the first lateral surface 210a and the second lateral surface 210b.

According to an example embodiment of the present inventive concept, since the first through electrodes 240 and the first molding layer 220 are disposed only on some of lateral surfaces of the first semiconductor chip 210, the first chip structure 200 may have a small planar area. As a result, it may be possible to provide a compact-sized semiconductor package.

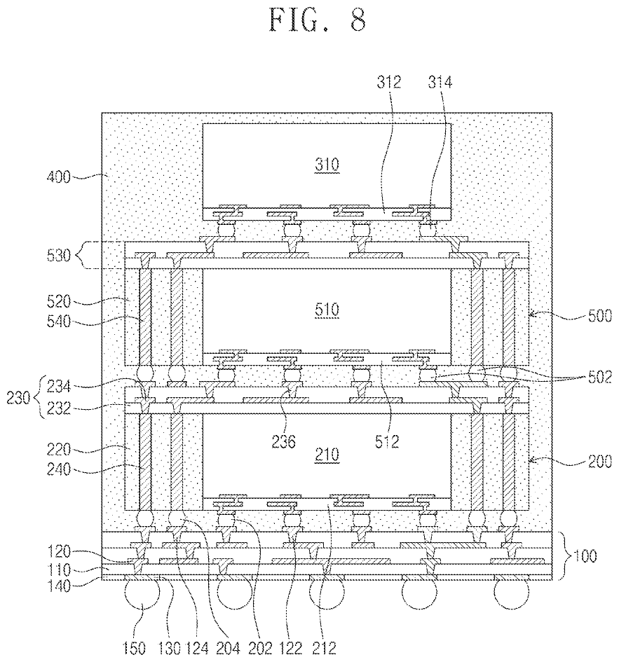

FIG. 8 illustrates a cross-sectional view showing a semiconductor device according to an example embodiment of the present inventive concept.

Referring to FIG. 8, a second chip structure 500 may be disposed between the first chip structure 200 and the second semiconductor chip 310. For example, the first chip structure 200 may be mounted on the package substrate 100, the second chip structure 500 may be mounted on the first redistribution layer 230 of the first chip structure 200, and the second semiconductor chip 310 may be mounted on the second chip structure 500.

A configuration of the second chip structure 500 may be substantially the same as or similar to that of the first chip structure 200. The second chip structure 500 may include a third semiconductor chip 510, a third molding layer 520, a second redistribution layer 530, and second through electrodes 540. The following will describe in detail the configuration of the second chip structure 500.

The third semiconductor chip 510 may include a semiconductor material, such as silicon (Si). The third semiconductor chip 510 may include a third circuit layer 512. The third semiconductor chip 510 may be of the same semiconductor chip as the first semiconductor chip 210. For example, the third circuit layer 512 may include a memory circuit. The third semiconductor chip 510 may be disposed in a face-down state on the first chip structure 200.

The third molding layer 520 may be disposed on a side of the third semiconductor chip 510. When viewed in a plan view, the third molding layer 520 may surround the third semiconductor chip 510. The third molding layer 520 may cover lateral surfaces of the third semiconductor chip 510. A top surface of the third molding layer 520 may be coplanar with that of the third semiconductor chip 510. A bottom surface of the third molding layer 520 may be coplanar with that of the third semiconductor chip 510. The third molding layer 520 may include a dielectric material, such as an epoxy molding compound (EMC).

At least one second through electrode 540 may be disposed on a side of the third semiconductor chip 510. The second through electrode 540 may be disposed horizontally spaced apart from the third semiconductor chip 510. The second through electrode 540 may vertically penetrate the third molding layer 520. One end of the second through electrode 540 may extend toward the first chip structure 200 to be exposed on the bottom surface of the third molding layer 520. The bottom surface of the third molding layer 520 may be flat, and a bottom surface of the second through electrode 540 may also be flat. A top surface of the second through electrodes 540 may be coplanar with that of the third molding layer 520. The top surface of the third molding layer 520 may be flat, and the top surface of the second through electrode 540 may also be flat. The second through electrode 540 may have a circular or polygonal pillar shape that vertically penetrates the third molding layer 520. When viewed in a plan view, the second through electrodes 540 may be disposed on opposite sides of the third semiconductor chip 510 or may be arranged to surround the third semiconductor chip 510. The second through electrodes 540 may include metal.

The second redistribution layer 530 may be disposed on the third semiconductor chip 510 and the third molding layer 520. The second redistribution layer 530 may be in direct contact with the top surface of the third semiconductor chip 510 and the top surface of the third molding layer 520. The second redistribution layer 530 may include one or more third substrate wiring layers that are stacked on each other. Each of the third substrate wiring layers may include a third substrate dielectric pattern and one or more third substrate wiring patterns in the third substrate dielectric pattern. When the third substrate wiring layer is provided in plural, the third substrate wiring pattern in one third substrate wiring layer may be electrically connected to the third substrate wiring pattern in an adjacent another third substrate wiring layer. The third substrate dielectric pattern may include a dielectric polymer or a photo-imageable dielectric (PID). The third substrate wiring pattern may be disposed on the third substrate dielectric pattern. The third substrate wiring pattern may horizontally extend on the third substrate dielectric pattern. The third substrate wiring pattern of a lowermost third substrate wiring layer may have a tail part coupled to the second through electrode 540.

The second chip structure 500 may be provided with fourth connection terminals 502 on a bottom surface thereof. The fourth connection terminals 502 may be disposed on the bottom surface of the third semiconductor chip 510 and the bottom surfaces of the second through electrodes 540. The fourth connection terminals 502 may include, for example, solder balls.

The second chip structure 500 may be mounted on the first chip structure 200. For example, the second chip structure 500 may be electrically connected through the fourth connection terminals 502 to the first redistribution layer 230 of the first chip structure 200.

The second semiconductor chip 310 may be mounted on the second chip structure 500. For example, the second semiconductor chip 310 may be electrically connected through the third connection terminals 314 to the second redistribution layer 530 of the second chip structure 500.

According to an example embodiment of the present inventive concept, the chip structures 200 and 500 may be vertically stacked to provide increased integration to a semiconductor package.

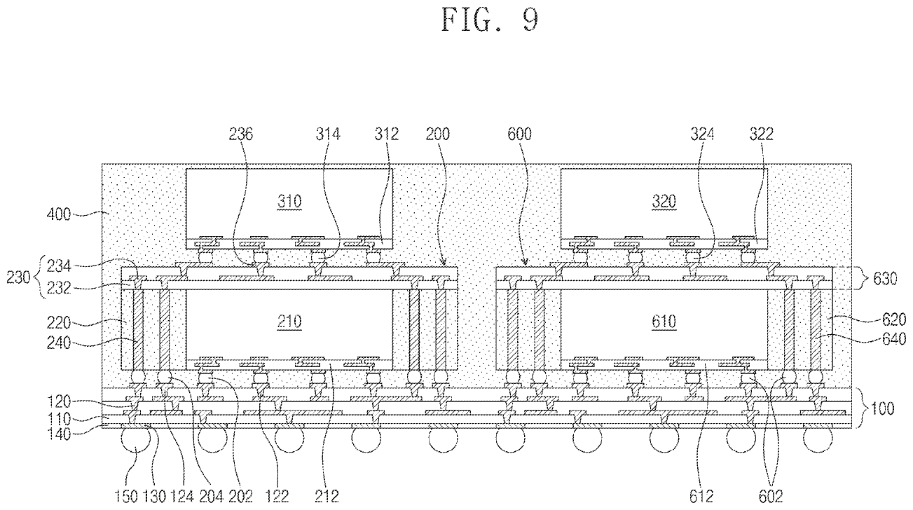

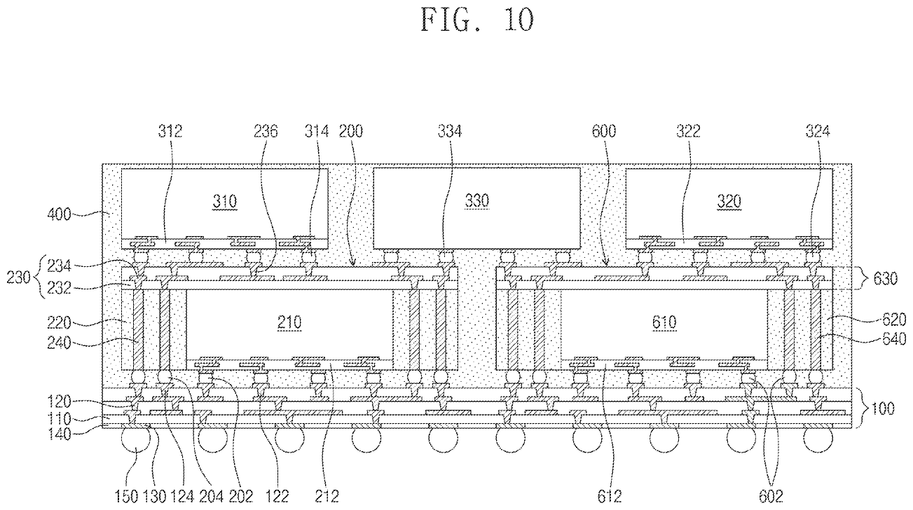

FIGS. 9 and 10 illustrate cross-sectional views showing a semiconductor device according to an example embodiment of the present inventive concept.

Referring to FIG. 9, a third chip structure 600 may be disposed on the package substrate 100. For example, the first chip structure 200 may be mounted on the package substrate 100, and the third chip structure 600 may be mounted on the package substrate 100 while being horizontally spaced apart from the first chip structure 200.

A configuration of the third chip structure 600 may be substantially the same as or similar to that of the first chip structure 200. The third chip structure 600 may include a fourth semiconductor chip 610, a fourth molding layer 620, a third redistribution layer 630, and third through electrodes 640.

The fourth semiconductor chip 610 may include a fourth circuit layer 612. The fourth circuit layer 612 may include a memory circuit. The fourth semiconductor chip 610 may be disposed in a face-down state on the package substrate 100.

The fourth molding layer 620 may be disposed on a side of the fourth semiconductor chip 610. When viewed in a plan view, the fourth molding layer 620 may surround the fourth semiconductor chip 610. The fourth molding layer 620 may cover lateral surfaces of the fourth semiconductor chip 610. A top surface of the fourth molding layer 620 may be coplanar with that of the fourth semiconductor chip 610. A bottom surface of the fourth molding layer 620 may be coplanar with that of the fourth semiconductor chip 610.

At least one third through electrode 640 may be disposed on a side of the fourth semiconductor chip 610. The third through electrode 640 may be disposed horizontally spaced apart from the fourth semiconductor chip 610. The third through electrode 640 may vertically penetrate the fourth molding layer 620. An end of the third through electrode 640 may extend toward the package substrate 100 to be exposed on the bottom surface of the fourth molding layer 620. The bottom surface of the fourth molding layer 620 may be flat, and a bottom surface of the third through electrode 640 may also be flat. A top surface of the third through electrodes 640 may be coplanar with that of the fourth molding layer 620. The top surface of the fourth molding layer 620 may be flat, and the top surface of the third through electrode 640 may also be flat. The third through electrode 640 may have a circular or polygonal pillar shape that vertically penetrates the fourth molding layer 620. When viewed in a plan view, the third through electrodes 640 may be disposed on opposite sides of the fourth semiconductor chip 610 or may be arranged to surround the fourth semiconductor chip 610.

The third redistribution layer 630 may be disposed on the fourth semiconductor chip 610 and the fourth molding layer 620. The third redistribution layer 630 may be in direct contact with the top surface of the fourth semiconductor chip 610 and the top surface of the fourth molding layer 620. The third redistribution layer 630 may include one or more fourth substrate wiring layers that are stacked on each other. Each of the fourth substrate wiring layers may include a fourth substrate dielectric pattern and one or more fourth substrate wiring patterns in the fourth substrate dielectric pattern. The fourth substrate wiring pattern may horizontally extend on the fourth substrate dielectric pattern. The fourth substrate wiring pattern of a lowermost fourth substrate wiring layer may have a tail part coupled to the third through electrode 640.

The third chip structure 600 may be disposed with fifth connection terminals 602 on a bottom surface thereof. The fifth connection terminals 602 may be disposed on the bottom surface of the fourth semiconductor chip 610 and the bottom surfaces of the third through electrodes 640.

The third chip structure 600 may be mounted on the package substrate 100. For example, the third chip structure 600 may be electrically connected through the fifth connection terminals 602 to the package substrate 100.

A fifth semiconductor chip 320 may be disposed on the third chip structure 600. The fifth semiconductor chip 320 may include a fifth circuit layer 322. The fifth semiconductor chip 320 may be of the same semiconductor chip as the fourth semiconductor chip 610. A bottom surface of the fifth semiconductor chip 320 may be an active surface, and a top surface of the fifth semiconductor chip 320 may be an inactive surface. For example, the fifth semiconductor chip 320 may be disposed in a face-down state on the third chip structure 600.

The fifth semiconductor chip 320 may be provided with sixth connection terminals 324 on the bottom surface thereof. The sixth connection terminals 324 may be electrically connected to an input/output circuit, a power circuit, or a ground circuit of the fifth semiconductor chip 320.

The fifth semiconductor chip 320 may be mounted on the third chip structure 600. For example, the fifth semiconductor chip 320 may be electrically connected through the sixth connection terminals 324 to the third redistribution layer 630 of the third chip structure 600.

The second molding layer 400 may be disposed on the package substrate 100. The second molding layer 400 may surround the first chip structure 200, the second semiconductor chip 310, the third chip structure 600, and the fifth semiconductor chip 320.

According to an example embodiment, as shown in FIG. 10, a sixth semiconductor chip 330 may be disposed on the first chip structure 200 and the third chip structure 600. A portion of the sixth semiconductor chip 330 may be positioned on the first chip structure 200, and another portion of the sixth semiconductor chip 330 may be positioned on the third chip structure 600. The sixth semiconductor chip 330 may be positioned between the second semiconductor chip 310 and the fifth semiconductor chip 320. The sixth semiconductor chip 330 may include a semiconductor chip including a transistor, a passive element chip including a passive element, or a thermal radiation member.

The sixth semiconductor chip 330 may be provided with seventh connection terminals 334 on a bottom surface thereof. Some of the seventh connection terminals 334 may be disposed between the sixth semiconductor chip 330 and the first redistribution layer 230 of the first chip structure 200, and others of the seventh connection terminals 334 may be disposed between the sixth semiconductor chip 330 and the third redistribution layer 630 of the third chip structure 600. The sixth semiconductor chip 330 may be mounted on the first chip structure 200 and the third chip structure 600. For example, the sixth semiconductor chip 330 may be connected through the seventh connection terminals 334 to the first redistribution layer 230 of the first chip structure 200 and to the third redistribution layer 630 of the third chip structure 600. When the sixth semiconductor chip 330 includes a semiconductor chip or a passive element chip, the sixth semiconductor chip 330 may be electrically connected to the package substrate 100 either through the first redistribution layer 230 and the first through electrodes 240 of the first chip structure 200 or through the third redistribution layer 630 and the third through electrodes 640 of the third chip structure 600. When the sixth semiconductor chip 330 includes a thermal radiation member, heat may be outwardly discharged through the sixth semiconductor chip 330 from the first semiconductor chip 210 and the fourth semiconductor chip 610.

According to an example embodiment of the present inventive concept, the sixth semiconductor chip 330 may be further disposed in a residual space between the second semiconductor chip 310 and the fifth semiconductor chip 320. Accordingly, it may be possible to provide a semiconductor package with increased integration or a semiconductor package with increased thermal radiation efficiency.

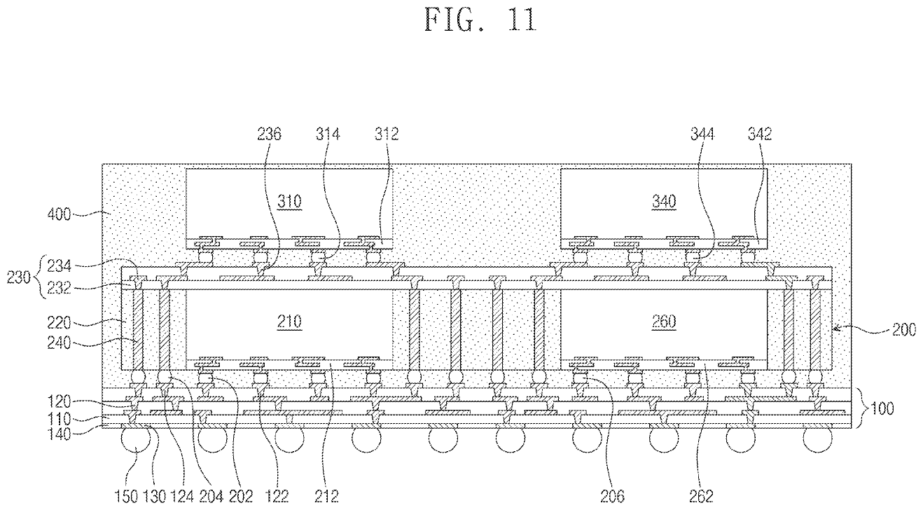

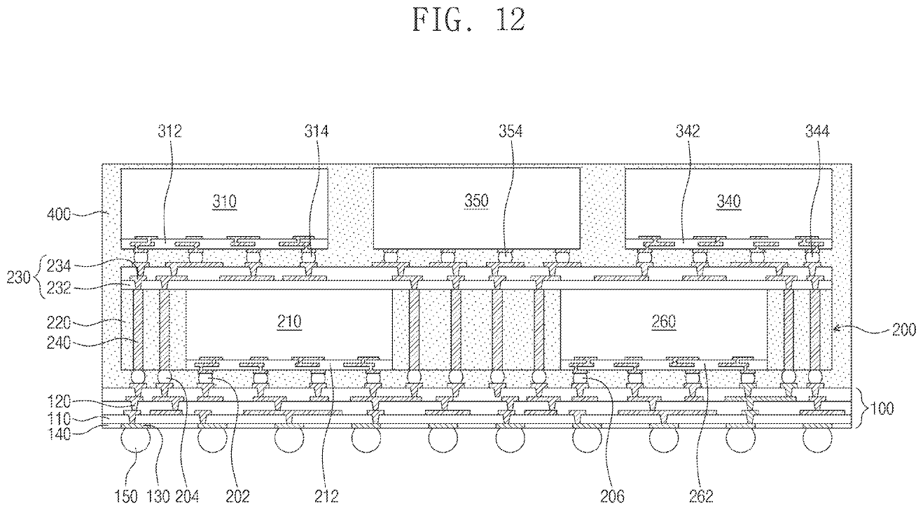

FIGS. 11 and 12 illustrate cross-sectional views showing a semiconductor device according to an example embodiment of the present inventive concept.

Referring to FIG. 11, the first chip structure 200 may further include a seventh semiconductor chip 260. The seventh semiconductor chip 260 may be disposed horizontally spaced apart from the first semiconductor chip 210. The seventh semiconductor chip 260 may include a sixth circuit layer 262. The sixth circuit layer 262 may include a memory circuit. The seventh semiconductor chip 260 may be disposed in a face-down state on the package substrate 100.

The first molding layer 220 may be disposed on a side of the first semiconductor chip 210 and a side of the seventh semiconductor chip 260. When viewed in a plan view, the first molding layer 220 may surround the first semiconductor chip 210 and the seventh semiconductor chip 260. The first molding layer 220 may cover lateral surfaces of the first semiconductor chip 210 and lateral surfaces of the seventh semiconductor chip 260. A top surface of the first molding layer 220 may be coplanar with that of the first semiconductor chip 210 and that of the seventh semiconductor chip 260. A bottom surface of the first molding layer 220 may be coplanar with that of the first semiconductor chip 210 and that of the seventh semiconductor chip 260.

One or more first through electrodes 240 may be disposed on a side of the first semiconductor chip 210 and a side of the seventh semiconductor chip 260. The first through electrodes 240 may be disposed horizontally spaced apart from the first semiconductor chip 210 and the seventh semiconductor chip 260. For example, when viewed in a plan view, the first through electrodes 240 may be arranged to surround the first semiconductor chip 210 and the seventh semiconductor chip 260 or may be arranged between the first semiconductor chip 210 and the seventh semiconductor chip 260.

The first redistribution layer 230 may be disposed on the first semiconductor chip 210, the seventh semiconductor chip 260, and the first molding layer 220. The first redistribution layer 230 may be in direct contact with the top surface of the first semiconductor chip 210, the top surface of the seventh semiconductor chip 260, and the top surface of the first molding layer 220. The first redistribution layer 230 may include one or more second substrate wiring layers that are stacked on each other. Each of the second substrate wiring layers may include a second substrate dielectric pattern 232 and one or more second substrate wiring patterns 234 on the second substrate dielectric pattern 232. The second substrate dielectric pattern 232 of a lowermost second substrate wiring layer may have a tail part coupled to the first through electrode 240.

The first chip structure 200 may be provided with connection terminals 202, 204, and 206 on a bottom surface thereof. The connection terminals 202, 204, and 206 may include first connection terminals 202 disposed on the bottom surface of the first semiconductor chip 210, second connection terminals 204 disposed on the bottom surfaces of the first through electrodes 240, and eighth connection terminals 206 disposed on the bottom surface of the seventh semiconductor chip 260. The first chip structure 200 may be mounted on the package substrate 100 through the connection terminals 202, 204, and 206.

The second semiconductor chip 310 may be mounted on the first chip structure 200. For example, the second semiconductor chip 310 may be electrically connected through the third connection terminals 314 to the first redistribution layer 230 of the first chip structure 200. The second semiconductor chip 310 may be electrically connected to the package substrate 100 through the first redistribution layer 230 and the first through electrodes 240 of the first chip structure 200. The second semiconductor chip 310 may be positioned above the first semiconductor chip 210.

A semiconductor package may further include an eighth semiconductor chip 340 disposed on the first chip structure 200. The eighth semiconductor chip 340 may include a seventh circuit layer 342. The eighth semiconductor chip 340 may be of the same semiconductor chip as the seventh semiconductor chip 260. A bottom surface of the eighth semiconductor chip 340 may be an active surface, and a top surface of the eighth semiconductor chip 340 may be an inactive surface. For example, the eighth semiconductor chip 340 may be disposed in a face-down state on the first chip structure 200.

The eighth semiconductor chip 340 may be mounted on the first chip structure 200. For example, the eighth semiconductor chip 340 may be electrically connected through ninth connection terminals 344 to the first redistribution layer 230 of the first chip structure 200. The eighth semiconductor chip 340 may be electrically connected to the package substrate 100 through the first redistribution layer 230 and the first through electrodes 240 of the first chip structure 200. The eighth semiconductor chip 340 may be positioned above the seventh semiconductor chip 260.

According to an example embodiments, as shown in FIG. 12, a ninth semiconductor chip 350 may be disposed on the first chip structure 200 and the third chip structure 600. The ninth semiconductor chip 350 may be positioned between the second semiconductor chip 310 and the eighth semiconductor chip 340. The ninth semiconductor chip 350 may include a semiconductor chip including a transistor, a passive element chip including a passive element, or a thermal radiation member.

The ninth semiconductor chip 350 may be mounted on the first chip structure 200. For example, the ninth semiconductor chip 350 may be connected through tenth connection terminals 354 to the first redistribution layer 230 of the first chip structure 200. When the ninth semiconductor chip 350 includes a semiconductor chip or a passive element chip, the ninth semiconductor chip 350 may be electrically connected to the package substrate 100 through the first redistribution layer 230 and the first through electrodes 240 of the first chip structure 200. When the ninth semiconductor chip 350 includes a thermal radiation member, heat may be outwardly discharged through the ninth semiconductor chip 350 from the first semiconductor chip 210 and the seventh semiconductor chip 260.

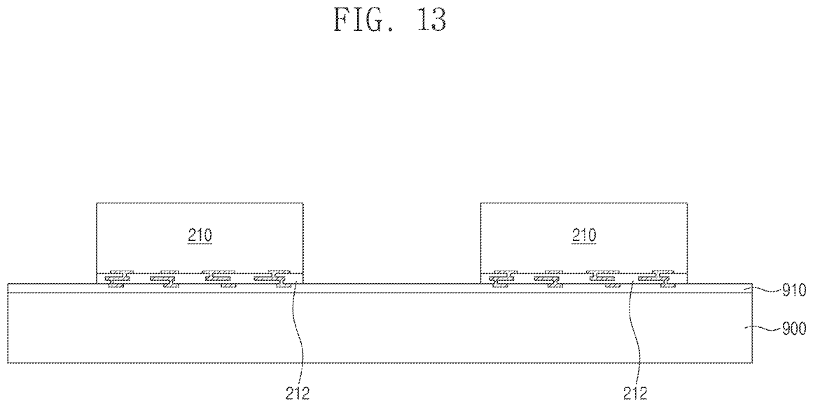

FIGS. 13, 14, 15, 16, 17, 18, 19 and 20 illustrate cross-sectional views showing a method of fabricating a semiconductor device according to an example embodiment of the present inventive concept.

Referring to FIG. 13, a carrier substrate 900 is provided. The carrier substrate 900 may be a dielectric substrate including glass or polymer, or may be a conductive substrate including metal. The carrier substrate 900 may be provided with an adhesive member 910 on a top surface of the carrier substrate 900. For example, the adhesive member 910 may include a glue tape.

First semiconductor chips 210 may be attached onto the carrier substrate 900. For example, the first semiconductor chips 210 may be disposed on the adhesive member 910. The first semiconductor chips 210 may be the same as or similar to the first semiconductor chip 210 discussed with reference to FIG. 1. The first semiconductor chips 210 may be disposed horizontally spaced apart from each other. The first semiconductor chips 210 may be attached to the carrier substrate 900 to allow their active surfaces to face toward the carrier substrate 900.

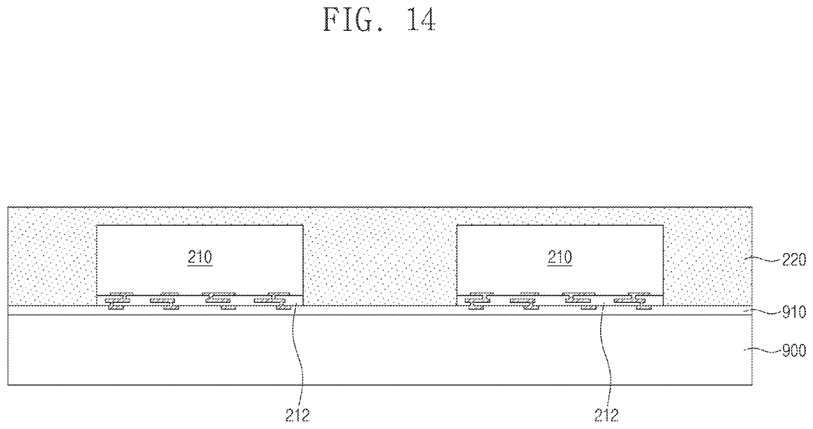

Referring to FIG. 14, a first molding layer 220 is formed on the carrier substrate 900. For example, a dielectric material may be coated on the carrier substrate 900, and then the dielectric material may be cured to form the first molding layer 220. On the carrier substrate 900, the first molding layer 220 may cover the first semiconductor chips 210. The first molding layer 220 may further cover the adhesive member 910.

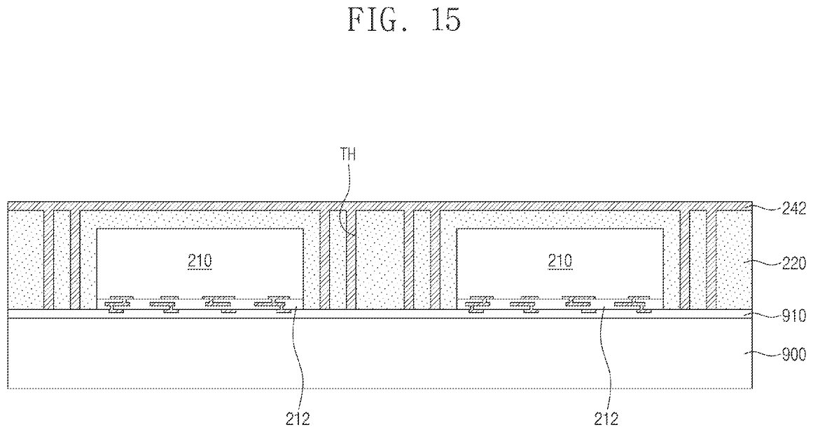

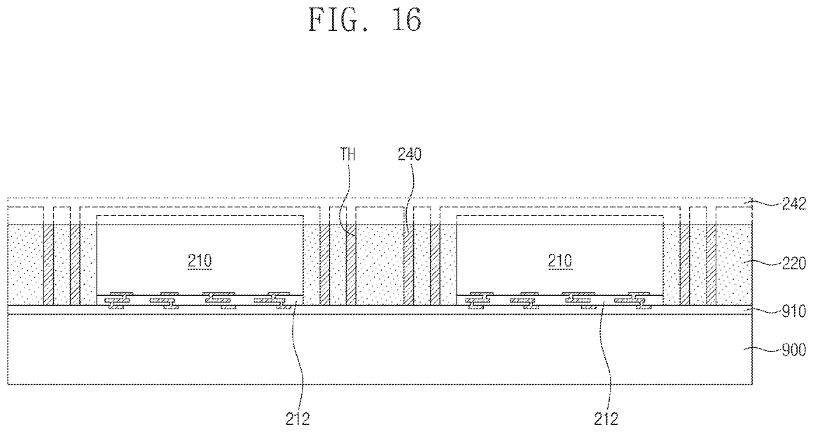

Referring to FIG. 15, the first molding layer 220 may be etched to form through holes TH. When viewed in a plan view, the through holes TH may be arranged to surround the first semiconductor chips 210. The through holes TH may vertically penetrate the first molding layer 220 to expose the carrier substrate 900 or the adhesive member 910 on the carrier substrate 900. The through holes TH may define areas where first through electrodes (see 240 of FIG. 16) are formed in a subsequent process.

A conductive layer 242 may be formed on the first molding layer 220. For example, a plating process may be used to form the conductive layer 242. The conductive layer 242 may fill the through holes TH and cover a top surface of the first molding layer 220. The conductive layer 242 may include a metallic material.

Referring to FIG. 16, the first molding layer 220 and the conductive layer 242 are partially removed. For example, a grinding process or a chemical mechanical polishing (CMP) process may be performed on a top surface of the conductive layer 242. The grinding process or a chemical mechanical polishing process may continue until the top surface of the first molding layer 220 is exposed. Therefore, the conductive layer 242 on the top surface of the first molding layer 220 may be removed, and the conductive layer 242 may be divided into first through electrodes 240 that remain in the through holes TH. If necessary, the grinding process or the chemical mechanical polishing process may be continuously performed to expose top surfaces of the first semiconductor chips 210. In this step, upper portions of the first semiconductor chips 210 may be removed to reduce a thickness of the first semiconductor chips 210. The first semiconductor chips 210, the first molding layer 220, and the first through electrodes 240 may have their top surfaces that are substantially coplanar with each other.

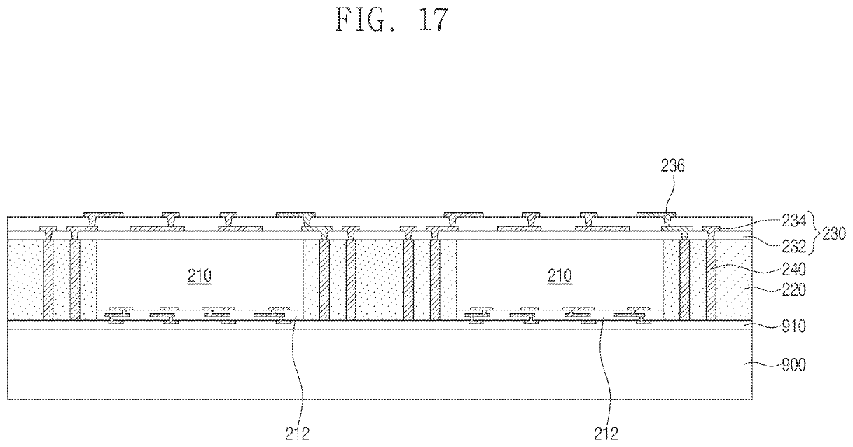

Referring to FIG. 17, a first redistribution layer 230 is formed on the first molding layer 220 and the first semiconductor chips 210. For example, a dielectric layer may be formed on the top surface of the first molding layer 220 and the top surfaces of the first semiconductor chips 210. The dielectric layer may be patterned to form a second substrate dielectric pattern 232, a conductive layer may be formed on the second substrate dielectric patterns 232, and the conductive layer may be patterned to form second substrate wiring patterns 234 to result in formation of a single second substrate wiring layer. The formation of the second substrate wiring layer may be repeatedly performed to form the first redistribution layer 230. Redistribution pads 236 may be defined to indicate the second substrate wiring patterns 234 disposed on an uppermost second substrate wiring layer.

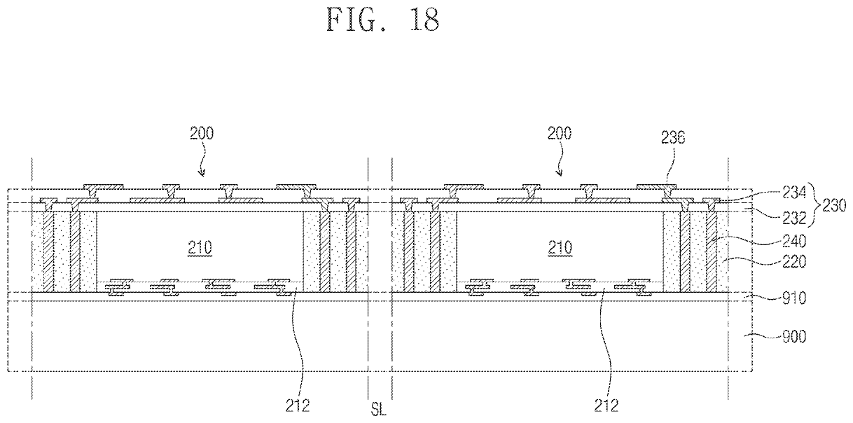

Referring to FIG. 18, the carrier substrate 900 undergoes a singulation process performed along a sawing line SL to form first chip structures 200 separated from each other. For example, the singulation process may sequentially cut the first redistribution layer 230 and the first molding layer 220. The sawing line SL may be positioned between the first semiconductor chips 210 to avoid cutting the first semiconductor chips 210 during the singulation process.

Afterwards, the carrier substrate 900 and the adhesive member 910 may be removed. Therefore, the first semiconductor chip 210 may be exposed at an active surface thereof, and the first through electrodes 240 may be exposed at bottom surfaces thereof.

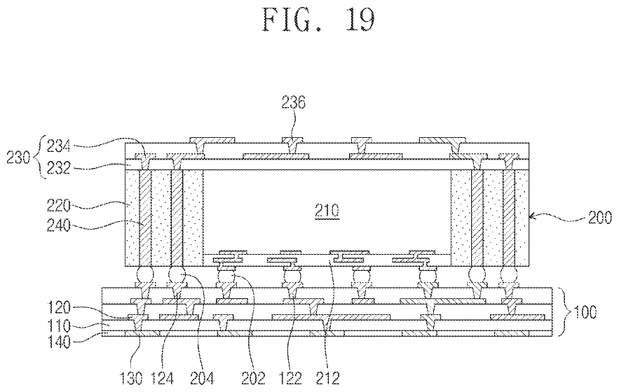

Referring to FIG. 19, a package substrate 100 is provided. The package substrate 100 may be the same as or similar to the package substrate 100 discussed with reference to FIG. 1.

Connection terminals 202 and 204 may be disposed on a bottom surface of the first chip structure 200. The connection terminals 202 and 204 may include first connection terminals 202 disposed on a bottom surface of the first semiconductor chip 210 and second connection terminals 204 disposed on the bottom surfaces of the first through electrodes 240.

The first chip structure 200 may be mounted on the package substrate 100. The first chip structure 200 may be flip-chip mounted on the package substrate 100. For example, the first chip structure 200 may be aligned on the package substrate 100 to allow the first connection terminals 202 to rest on first substrate pads 122 of the package substrate 100 and also to allow the second connection terminals 204 to rest on second substrate pads 124 of the package substrate 100. Thereafter, a reflow process may be performed to couple the first connection terminals 202 to the first substrate pads 122 of the package substrate 100 and also to couple the second connection terminals 204 to the second substrate pads 124 of the package substrate 100.

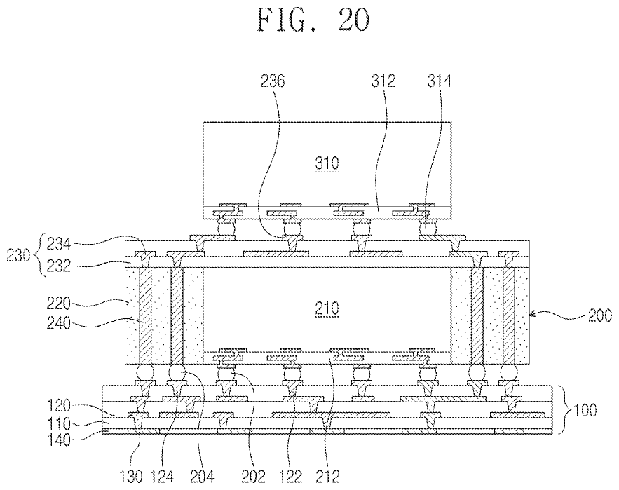

Referring to FIG. 20, a second semiconductor chip 310 is provided. The second semiconductor chip 310 may be the same as or similar to the second semiconductor chip 310 discussed with reference to FIG. 1. The second semiconductor chip 310 may be provided with third connection terminals 314 on a bottom surface thereof.

The second semiconductor chip 310 may be mounted on the first chip structure 200. The second semiconductor chip 310 may be flip-chip mounted on the first chip structure 200. For example, the second semiconductor chip 310 may be aligned on the first chip structure 200 to allow the third connection terminals 314 to rest on the redistribution pads 236. After that, a reflow process may be performed to couple the third connection terminals 314 to the redistribution pads 236. According to an example embodiment, the reflow process for mounting the first chip structure 200 may be performed simultaneously with the reflow process for mounting the second semiconductor chip 310.

Referring back to FIG. 1, a second molding layer 400 may be formed on the package substrate 100. For example, a dielectric material may be coated on the package substrate 100 so as to cover the first chip structure 200 and the second semiconductor chip 310, and then the dielectric material may be cured to form the second molding layer 400.

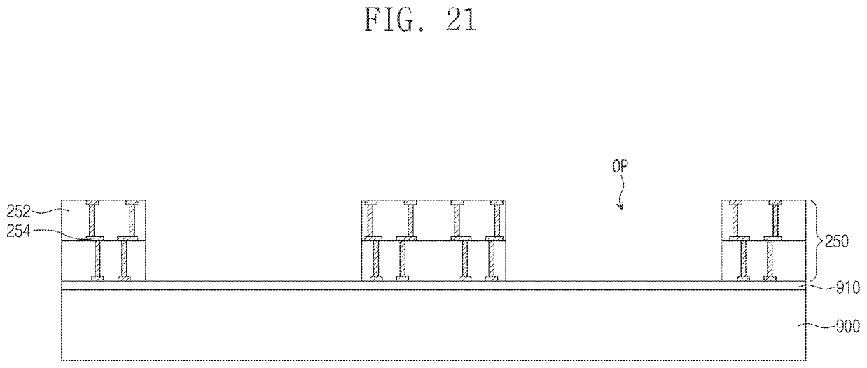

FIGS. 21, 22, 23, 24 and 25 illustrate cross-sectional views showing a method of fabricating a semiconductor device according to an example embodiment of the present inventive concept.

Referring to FIG. 21, a carrier substrate 900 is provided. The carrier substrate 900 may be provided with an adhesive member 910 on a top surface of the carrier substrate 900.

A connection substrate 250 may be attached onto the carrier substrate 900. The connection substrate 250 may be the same as or similar to the connection substrate 250 discussed with reference to FIG. 3. The connection substrate 250 may have openings OP that penetrate therethrough. The connection substrate 250 may be disposed on the adhesive member 910.

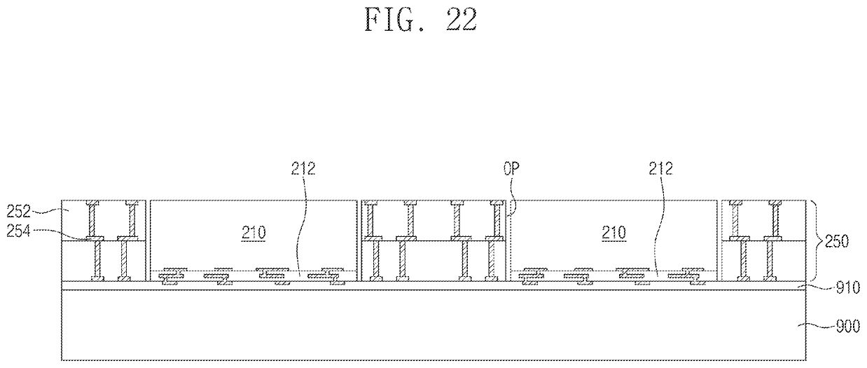

Referring to FIG. 22, first semiconductor chips 210 are attached onto the carrier substrate 900. For example, the first semiconductor chips 210 may be disposed on the adhesive member 910. The first semiconductor chips 210 may be the same as or similar to the first semiconductor chip 210 discussed with reference to FIG. 3. The first semiconductor chips 210 may be correspondingly disposed in the openings OP of the connection substrate 250. The first semiconductor chips 210 may be spaced apart from inner lateral surfaces of the openings OP. The first semiconductor chips 210 may be attached to the carrier substrate 900 to allow their active surfaces to face toward the carrier substrate 900.

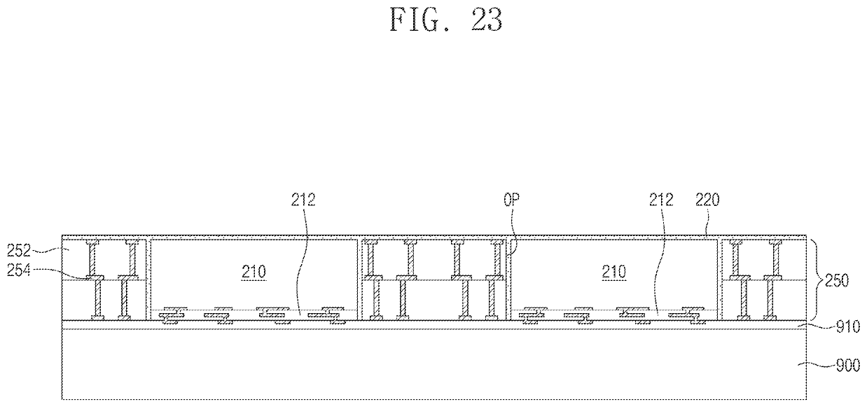

Referring to FIG. 23, a first molding layer 220 is formed on the carrier substrate 900. For example, a first molding layer 220 may be formed on the first semiconductor chips 210 and to fill the openings OP. For example, a dielectric material may be coated on the carrier substrate 900, and then the dielectric material may be cured to form the first molding layer 220. The first molding layer 220 may cover the connection substrate 250, and spaces between the connection substrate 250 and the first semiconductor chips 210 may be filled with the first molding layer 220 in the openings OP.

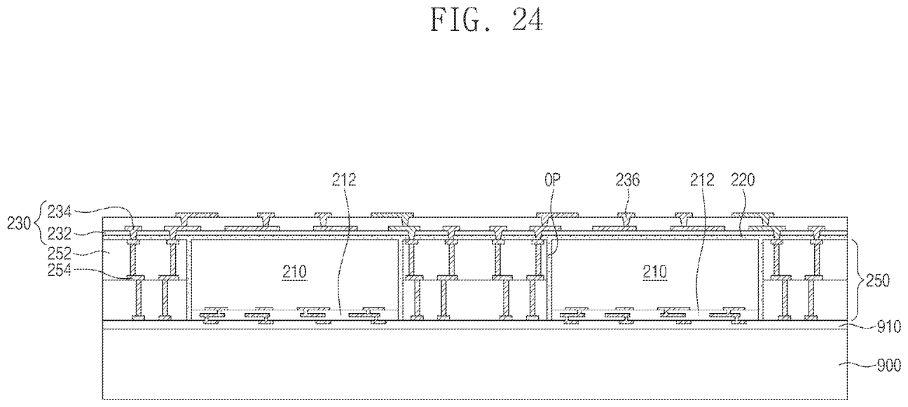

Referring to FIG. 24, a first redistribution layer 230 is formed on the connection substrate 250 and the first semiconductor chips 210. For example, a dielectric layer may be formed on a top surface of the first molding layer 220, the dielectric layer may be patterned to form a second substrate dielectric pattern 232, a conductive layer may be formed on the second substrate dielectric pattern 232, and the conductive layer may be patterned to form second substrate wiring patterns 234, to result in formation of a single second substrate wiring layer. The formation of the second substrate wiring layer may be repeatedly performed to form the first redistribution layer 230. Redistribution pads 236 may be defined to indicate the second substrate wiring patterns 234 disposed on an uppermost second substrate wiring layer.

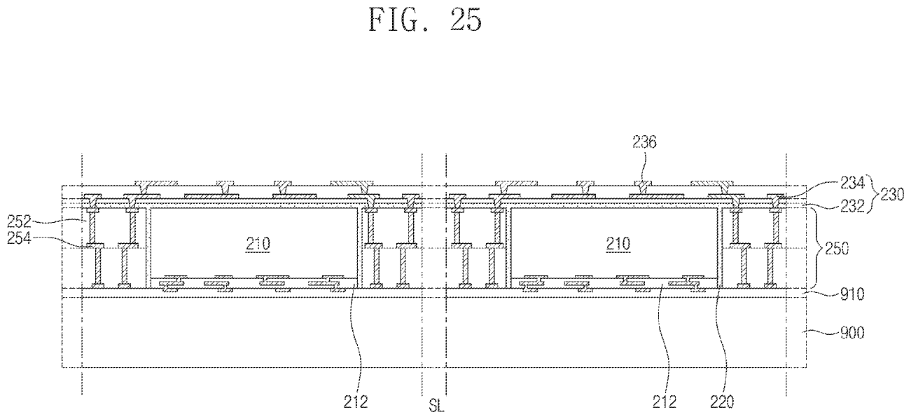

Referring to FIG. 25, the carrier substrate 900 may undergo a singulation process performed along a sawing line SL to form first chip structures 200 separated from each other. For example, the singulation process may sequentially cut the first redistribution layer 230, the first molding layer 220, and the connection substrate 250. The sawing line SL may be positioned between the first semiconductor chips 210 to avoid cutting the first semiconductor chips 210 during the singulation process.

Afterwards, the carrier substrate 900 and the adhesive member 910 may be removed. Therefore, the first semiconductor chips 210 may be exposed at active surfaces thereof, and the connection substrate 250 may be exposed at a bottom surface thereof.

Referring back to FIG. 3, a package substrate 100 may be provided. The package substrate 100 may be the same as or similar to the package substrate 100 discussed with reference to FIG. 3.

Connection terminals 202 and 204 may be disposed on a bottom surface of the first chip structure 200. The connection terminals 202 and 204 may include first connection terminals 202 disposed on a bottom surface of the first semiconductor chip 210 and second connection terminals 204 disposed on bottom surfaces of lower pads 254p2 in the connection substrate 250.

The first chip structure 200 may be mounted on the package substrate 100. For example, the first chip structure 200 may be aligned on the package substrate 100 to allow the first connection terminals 202 to rest on first substrate pads 122 of the package substrate 100 and also to allow the second connection terminals 204 to rest on second substrate pads 124 of the package substrate 100. Thereafter, a reflow process may be performed to couple the first connection terminals 202 to the first substrate pads 122 of the package substrate 100 and also to couple the second connection terminals 204 to the second substrate pads 124 of the package substrate 100.

A second semiconductor chip 310 may be provided. The second semiconductor chip 310 may be the same as or similar to the second semiconductor chip 310 discussed with reference to FIG. 3. The second semiconductor chip 310 may be provided with third connection terminals 314 on a bottom surface thereof.

The second semiconductor chip 310 may be mounted on the first chip structure 200. For example, the second semiconductor chip 310 may be aligned on the first chip structure 200 to allow the third connection terminals 314 to rest on the redistribution pads 236. After that, a reflow process may be performed to couple the third connection terminals 314 to the redistribution pads 236. According to an example embodiment, the reflow process for mounting the first chip structure 200 is performed simultaneously with the reflow process for mounting the second semiconductor chip 310.

A second molding layer 400 may be formed on the package substrate 100. For example, a dielectric material may be coated on the package substrate 100 so as to cover the first chip structure 200 and the second semiconductor chip 310, and then the dielectric material may be cured to form the second molding layer 400.

In a semiconductor package according to an example embodiment of the present inventive concept, semiconductor chips may be vertically stacked even without forming through vias that penetrate the semiconductor chips. In addition, the semiconductor chips may be mounted in a flip-chip bonding manner whose electrical connection length is less than that of a wire bonding manner. Accordingly, it may be possible to provide a semiconductor package whose manufacturing cost is reduced and whose electrical properties are increased.

Moreover, the semiconductor chips may partially share a circuit of a package substrate, and thus there may be a reduction in area required for wiring of the package substrate. As a result, it may be possible to provide a compact-sized semiconductor package. Further, it may be possible to provide a semiconductor package with fewer wiring lines in the package substrate and with increased electrical properties.

Although the present inventive concept has been described in connection with some embodiments illustrated in the accompanying drawings, it will be understood by one of ordinary skill in the art that variations in form and detail may be made therein without departing from the spirit of the present inventive concept. The above disclosed embodiments should thus be considered illustrative and not restrictive.

1. A semiconductor package, comprising:
a package substrate;
a first chip structure mounted on the package substrate;
a first semiconductor chip mounted on the first chip structure; and
a first molding layer that surrounds the first chip structure and the first semiconductor chip on the package substrate,
wherein the first chip structure comprises:
a second semiconductor chip;
a second molding layer disposed on a lateral surface of the second semiconductor chip;
a first redistribution layer disposed on the second semiconductor chip and the second molding layer; and
a first through electrode disposed on a side of the second semiconductor chip and connected to the first redistribution layer.

2. The semiconductor package of claim 1, wherein
the second semiconductor chip is mounted on the package substrate through a first connection terminal between the second semiconductor chip and the package substrate,
the first through electrode vertically penetrates the first molding layer and has a bottom surface exposed on a bottom surface of the first molding layer, and
the first through electrode is mounted on the package substrate through a second connection terminal between the package substrate and the bottom surface of the first through electrode.

3. The semiconductor package of claim 1, wherein
when viewed in a plan view, the second molding layer surrounds the second semiconductor chip, and
the first through electrode is provided in plural, and the plurality of first through electrodes are arranged to surround the second semiconductor chip.

4. The semiconductor package of claim 1, wherein the first semiconductor chip is mounted on the first redistribution layer through a third connection terminal between the first semiconductor chip and the first redistribution layer.

5. The semiconductor package of claim 1, wherein at least a portion of the first semiconductor chip vertically overlaps the second molding layer.

6. The semiconductor package of claim 1, wherein
the first chip structure further includes a third semiconductor chip horizontally spaced apart from the second semiconductor chip,
the second molding layer surrounds the first semiconductor chip and the third semiconductor chip, and
the first redistribution layer is on the second semiconductor chip, the third semiconductor chip, and the second molding layer.

7. The semiconductor package of claim 6, further comprising a fourth semiconductor chip on the first chip structure and horizontally spaced apart from the first semiconductor chip, the fourth semiconductor chip being mounted on a first redistribution layer of the first chip structure,
wherein the first semiconductor chip is on the second semiconductor chip, and
wherein the fourth semiconductor chip is on the third semiconductor chip.

8. The semiconductor package of claim 6, further comprising a fifth semiconductor chip between the first semiconductor chip and the fourth semiconductor chip on the first chip structure, the fifth semiconductor chip being mounted on a first redistribution layer of the first chip structure,
wherein the fifth semiconductor chip is on the second molding layer.

9. The semiconductor package of claim 1, further comprising:
a second chip structure spaced apart from the first chip structure on the package substrate, the second chip structure being mounted on the package substrate; and
a third semiconductor chip mounted on the second chip structure,
wherein the first molding layer surrounds the first chip structure, the first semiconductor chip, the second chip structure, and the third semiconductor chip,
wherein the second chip structure comprises:
a fourth semiconductor chip;
a third molding layer on a lateral surface of the fourth semiconductor chip;
a second redistribution layer on the fourth semiconductor chip and the third molding layer; and
a second through electrode that vertically penetrates the third molding layer and is connected to the second redistribution layer.

10. The semiconductor package of claim 9, further comprising an fifth semiconductor chip between the first semiconductor chip and the third semiconductor chip,
wherein the fifth semiconductor chip overlaps a portion of the first chip structure and a portion of the second chip structure.

11. (canceled)

12. The semiconductor package of claim 1, further comprising a second chip structure mounted on the first chip structure,
wherein the second chip structure comprises:
a third semiconductor chip;
a third molding layer on a lateral surface of the ninth semiconductor chip;
a second redistribution layer on the third semiconductor chip and the third molding layer; and
a second through electrode that vertically penetrates the third molding layer and is connected to the second redistribution layer,
wherein the first semiconductor chip is mounted on the second chip structure and is connected to the first redistribution layer of the first chip structure through the second through electrode and the second redistribution layer of the second chip structure.

13. The semiconductor package of claim 1, wherein the first through electrode vertically penetrates the second molding layer, the first through electrode being coupled to the first redistribution layer and exposed on a bottom surface of the second molding layer.

14. The semiconductor package of claim 1, further comprising a connection substrate below the first redistribution layer and coupled to the first redistribution layer, the connection substrate having an opening that penetrates the connection substrate,
wherein the second semiconductor chip is in the opening of the connection substrate,
wherein, in the opening, the second molding layer fills a space between the connection substrate and the second semiconductor chip, and
wherein the first through electrode corresponds to a wiring pattern in the connection substrate.

15. A semiconductor package, comprising:
a package substrate;
a first semiconductor chip flip-chip mounted on the package substrate;
a first molding layer that surrounds a lateral surface of the first semiconductor chip;
a first through electrode that vertically penetrates the first molding layer and is mounted on the package substrate through a first connection terminal on a bottom surface of the first molding layer;
a first redistribution layer disposed on the first semiconductor chip and the first molding layer, the first redistribution layer being coupled to the first through electrode;
a second semiconductor chip flip-chip mounted on the first redistribution layer; and
a second molding layer disposed on the package substrate, the second molding layer covering the first molding layer, the first redistribution layer, and the second semiconductor chip.

16. The semiconductor package of claim 15, wherein at least a portion of the second semiconductor chip vertically overlaps the first molding layer.

17. The semiconductor package of claim 15, further comprising a third semiconductor chip horizontally spaced apart from the first semiconductor chip and flip-chip mounted on the package substrate,
wherein the first molding layer surrounds the first semiconductor chip and the third semiconductor chip, and
wherein the first redistribution layer is on the first semiconductor chip, the third semiconductor chip, and the first molding layer.

18-20. (canceled)

21. A semiconductor package, comprising:
a package substrate;
a first chip structure on the package substrate; and
a first semiconductor chip on the first chip structure,
wherein the first chip structure comprises:
a second semiconductor chip;
a vertical connection terminal on a side of the second semiconductor chip; and
a first redistribution layer on the second semiconductor chip and the vertical connection terminal, the first redistribution layer being electrically connected to the vertical connection terminal, and on which is mounted the first semiconductor chip,
wherein the second semiconductor chip is mounted on the package substrate through a first connection terminal between the package substrate and the second semiconductor chip, and
wherein the vertical connection terminal is mounted on the package substrate through a second connection terminal between the package substrate and the vertical connection terminal.

22. The semiconductor package of claim 21, wherein
the first chip structure further includes a first molding layer that surrounds the second semiconductor chip,
the first redistribution layer covers the first molding layer and the second semiconductor chip, and
the vertical connection terminal includes a through electrode that vertically penetrates the first molding layer, the through electrode being coupled to the first redistribution layer.

23-24. (canceled)

25. The semiconductor package of claim 21, wherein
the second semiconductor chip is in a face-down state on the package substrate, and
the first redistribution layer is on inactive surface of the second semiconductor chip.

26. (canceled)

27. The semiconductor package of claim 21, wherein at least a portion of the first semiconductor chip vertically overlaps the first molding layer.

28. (canceled)
